(19) United States
(12) Patent Application Publication
(10) Pub. No.: US 2013/0235512 A1
(43) Pub. Date: Sep. 12, 2013

(54) ELECTRONIC DEVICE WITH RETRACTABLE KEYBOARD

(71) Applicants: PO-CHING CHIANG, Tu-Cheng (TW); NI-CHUN HOU, Tu-Cheng (TW)

(72) Inventors: PO-CHING CHIANG, Tu-Cheng (TW); NI-CHUN HOU, Tu-Cheng (TW)

(73) Assignee: HON HAI PRECISION INDUSTRY CO., LTD., Tu-Cheng (TW)

(21) Appl. No.: 13/482,451

(22) Filed: May 29, 2012

(30) Foreign Application Priority Data
Mar. 6, 2012 (TW) 101107402

(51) Int. Cl. H05K 7/00

(52) U.S. Cl. 361/679.01

(57) ABSTRACT

An electronic device includes a base member, a display member pivotally coupled to the base member, and a keyboard disposed on an upper surface of the base member. The keyboard includes a plurality of keys and a plurality of lifting members. The plurality of lifting members is adapted to move the plurality of keys to stored positions when the display member is moved to an closed position.

### BACKGROUND

1. Technical Field

The present disclosure generally relates to an electronic device, and particularly relates to an electronic device with a retractable keyboard.

2. Description of Related Art

Notebook (also called laptop or mobile) computers are typically light and compact comparing to desktop computers. Features of light weight and compact size have made using notebook computers common activities. FIG. 1 illustrates a conventional notebook computer 10, which generally includes a base member 14, a display member 12 pivotally coupled to the base member 14, and a keyboard 15 disposed on a working surface of the base member 14. The keyboard 15 includes a plurality of keys 16, which all protrude from the working surface of the base member 14. Keycaps of the plurality of keys 16 are higher than the working surface of the base member 14 such that an extra space must be defined between the base member 14 and the display member 12 to accommodate the plurality of keys 16 when the display member 12 is moved to a closed position as shown in FIG. 1. The extra space makes the notebook computer 10 significantly thicker in size.

Therefore, a need may be desired to provide a notebook computer with an improved keyboard which does not requires extra space.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of a conventional notebook computer.

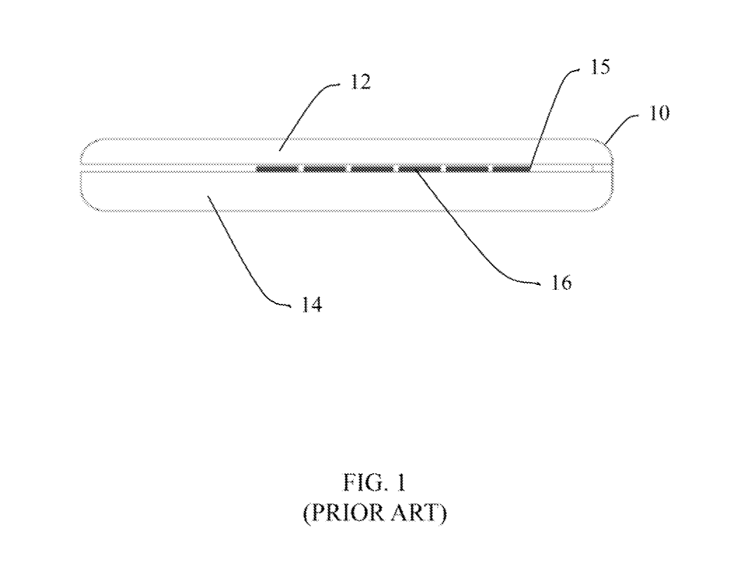

FIG. 2 is a schematic view of a notebook computer employing an improved keyboard to advantage in accordance with an embodiment.

FIG. 3 is similar to FIG. 2, but viewed from a different aspect.

FIG. 4 is similar to FIG. 3, but showing the display member in a closed position.

FIG. 5 is a cross-sectional view of a key of the improved keyboard in accordance with an embodiment.

FIG. 6 is similar to FIG. 5, but showing the key in a stored position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

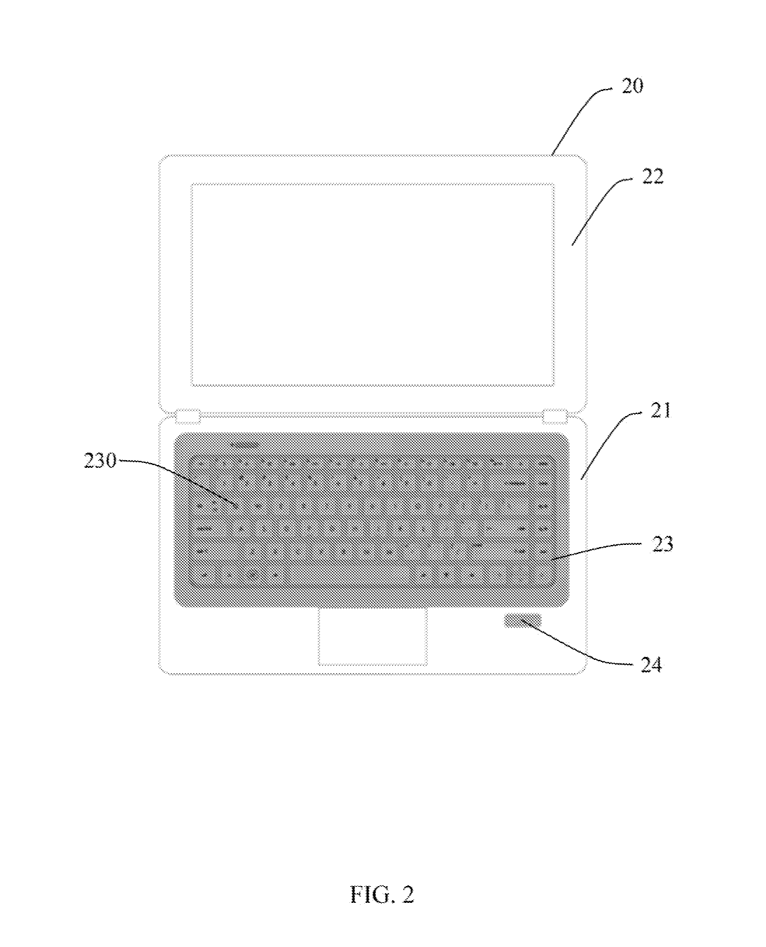

FIGS. 2-4, show an electronic device 20 employing an embodiment of an improved keyboard 23 to advantage. In the embodiment illustrated in FIGS. 2-4, the electronic device 20 is a notebook computer. However, it should be understood that the electronic device 20 may be any type of electronic device such as, but not limited to, a tablet personal computer, a personal digital assistant, a gaming device, a digital video disk (DVD) player, a radio, a television, a coffee maker, or any other type of portable or non-portable electronic device.

In the embodiment illustrated in FIGS. 2-4, the electronic device 20 comprises a base member 21, a display member 22 pivotally coupled to the base member 21 to enable variable positioning of the display member 22 relative to the base member 21. The improved keyboard 23 is disposed on a working surface of the base member 21. The improved keyboard 23 comprises a plurality of keys 230. The interior of the base member 21 may further comprise a number of computer components (not shown), such as a mother board, a central processing unit (CPU), storage devices, and any type of I/O device.

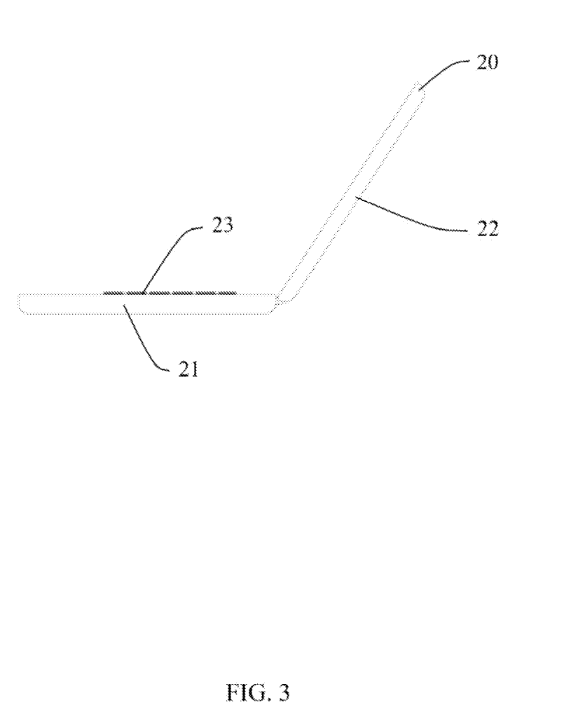

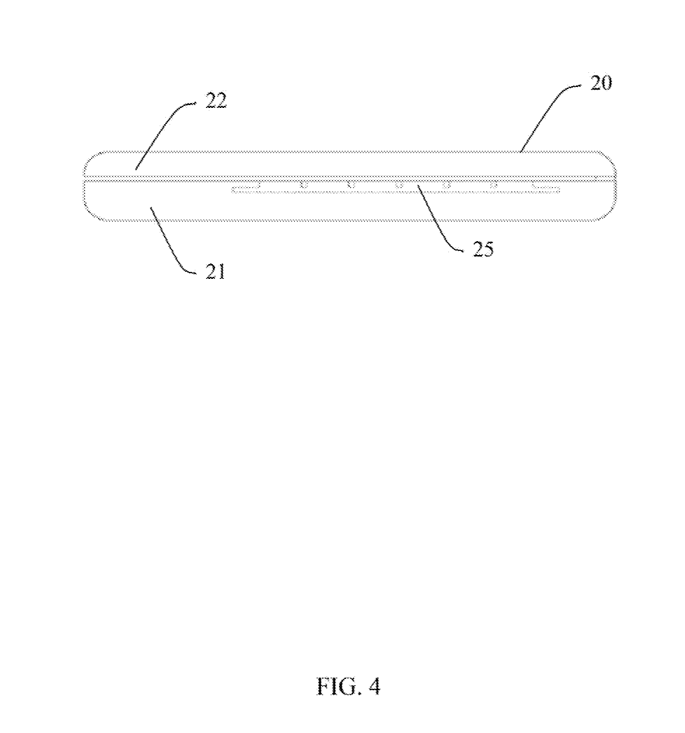

The display member 22 may be moved between an open position (shown as FIGS. 2 and 3) and a closed position (shown as in FIG. 4). When the display member 22 is in the open position, the display member 22 is away from the base member 21. When the display member 22 is in the closed position, the display member 22 comes down on the base member 21.

The base member 21 defines a plurality of receiving cavities 25 to receive the plurality of keys 230 of the improved keyboard 23. The number of the receiving cavities 25 is the same as the number of the plurality of keys 230. Namely, each receiving cavity 25 may receive a key of the plurality of keys 230.

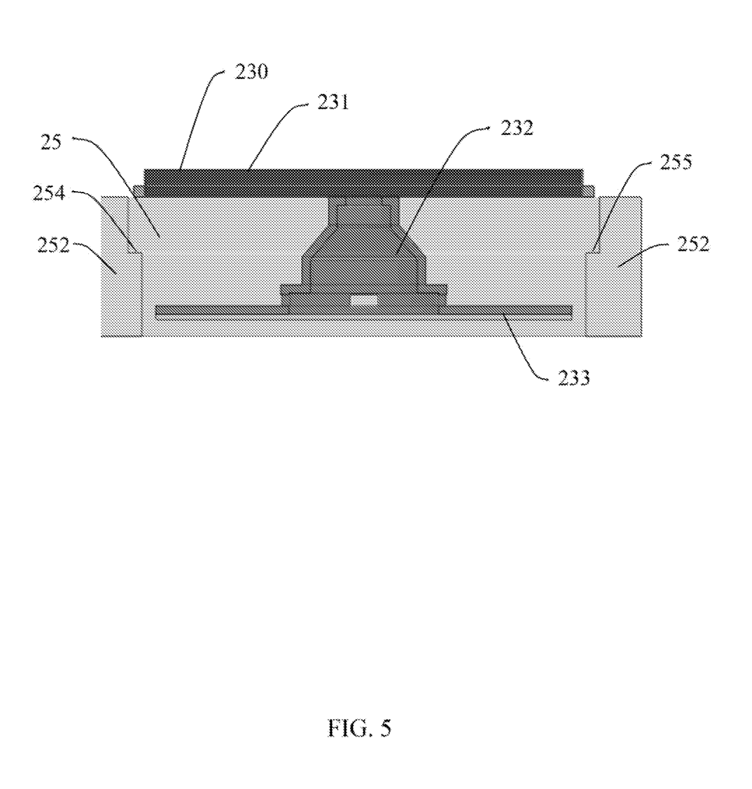

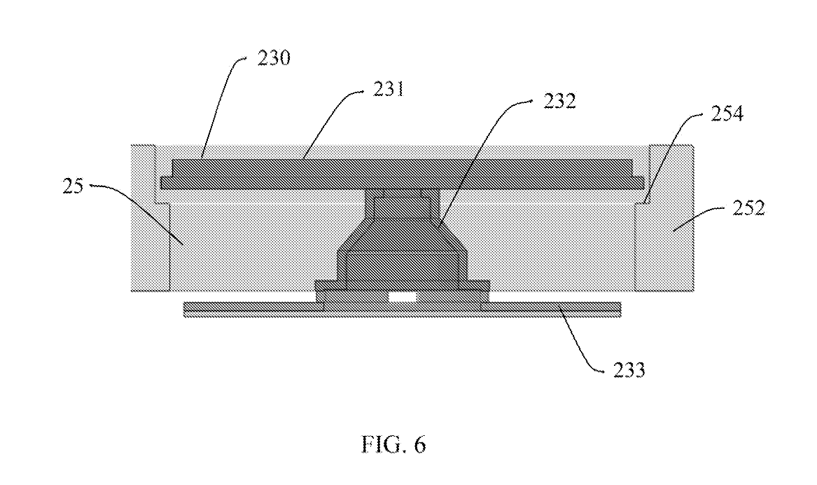

Referring to FIGS. 5 and 6, a cross-sectional view of the key of the plurality of keys 230 is shown. The key 230 generally comprises a keycap 231, an elastic member 232, and a membrane circuit board (not shown). When the keycap 231 is pressed down, the elastic member 232 is deformed and the membrane circuit is touched to generate a key signal. A lifting member 233 is coupled to the bottom of each key 230. The lifting member 233 includes a spring, a cylinder, or any other mechanism which may move one of the plurality of keys 233 upwards or downwards. A blocking mechanism 254 is defined in each of the plurality of cavities 25. The blocking mechanism 254 comprises a blocking plate 255 located on each of two sidewalls 252 of the cavity 25.

Referring to FIGS. 2, 3, and 5, when the display member 22 is moved to the open position, each of the lifting member 233 moves a key 230 upwards to an extended position. The keycap 231 of the key 230 is moved away from the cavity 25 to a point higher than the working surface of the base member 21, such that a user can press down the key 230 to input key strokes.

Referring to FIGS. 4 and 6, when the display member 22 is moved to the closed position, each of the lifting member 233 moves a key 230 downwards to a stored position, in which the keycap 231 of the key 230 is received in the cavity 25 and substantially abuts two of the blocking plates 255, such that two of the blocking plates 255 prevent the key 230 from being pressed down further. Thus, there is no need for any extra space to accommodate the key board 230 when the display member 22 is in the closed position.

Referring to FIG. 2, the electronic device 20 further comprises a light sensor 24 disposed on the working surface of the base member 21 in accordance with another embodiment. The light sensor 24 may detect an object such as a hand or a finger appearing above the light sensor 24. When the light sensor 24 detects an object at a predetermined distance above the light sensor 24, such as 10 centimeters, the light sensor generates an extending instruction and all of the lifting members 233 move the keys 230 to the extended positions in response to the extending instruction. When the light sensor 24 has detected no object within the predetermined distance for a predetermined period of time, such as 6 minutes, the light sensor generates a retracting instruction and the lifting members 233 moves the keys 230 to the stored positions in response to the retracting instruction.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device, comprising:
a base member;
a display member pivotally coupled to the base member; and
a keyboard disposed on an upper surface of the base member, the keyboard comprises a plurality of keys and a plurality of lifting members, wherein the plurality of lifting members are adapted to move the plurality of keys to stored positions when the display member is moved to a closed position.

2. The electronic device of claim 1, wherein the plurality of lifting members are adapted to move the plurality of keys to extended positions when the display member is moved to an open position.

3. The electronic device of claim 2, wherein the base member defines a plurality of receiving cavities adapted to receive the plurality of keys when the plurality of keys are moved to the stored positions.

4. The electronic device of claim 3, wherein the plurality of lifting members are adapted to move the plurality of keys away from the plurality of receiving cavities when the plurality of keys are moved to the extended positions.

5. The electronic device of claim 3, further comprising a plurality of blocking mechanisms defined in the plurality of receiving cavities, the plurality of blocking mechanisms are adapted to prevent the plurality of keys from being pressed down when the plurality of keys are retracted in the plurality of receiving cavities.

6. The electronic device of claim 5, wherein each of the plurality of blocking mechanism comprises two blocking plates; each of the plurality of receiving cavities defines two sidewalls, each of the two blocking plates being located on each of the two sidewalls.

7. A keyboard, comprising:
a plurality of keys arranged on a working surface of a base member of an electronic device; and
a plurality of lifting members adapted to move the plurality of keys to stored positions when a display member of the electronic device is moved to a closed position.

8. The keyboard of claim 7, wherein the plurality of lifting members are adapted to move the plurality of keys to extended positions when the display member is moved to an open position.

9. The keyboard of claim 8, wherein the plurality of lifting members are adapted to retract the plurality of keys into a plurality of receiving cavities of the base member when the plurality of keys are moved to the stored positions.

10. The keyboard of claim 9, wherein the plurality of lifting members are adapted to move the plurality of keys away from the plurality of receiving cavities when the plurality of keys are moved to the extended positions.

11. The keyboard of claim 9, further comprising a plurality of blocking mechanisms defined in the plurality of receiving cavities, the plurality of blocking mechanisms are adapted to prevent the plurality of keys from being pressed down when the plurality of keys are retracted in the plurality of receiving cavities.

12. The keyboard of claim 11, wherein each of the plurality of blocking mechanism comprises two blocking plates each of the plurality of receiving cavities defines two sidewalls, each of the two blocking plates being located on each of the two sidewalls.

13. An electronic device, comprising:
a base member;
a keyboard disposed on a working surface of the base member, the keyboard comprises a plurality of keys and a plurality of lifting members, wherein the plurality of lifting members are adapted to move the plurality of keys to stored positions in response to a retracting instruction.

14. The electronic device of claim 13, wherein the plurality of lifting members are adapted to move the plurality of keys to extended positions in response to an extending instruction.

15. The electronic device of claim 14, wherein the base member defines a plurality of receiving cavities adapted to receive the plurality of keys when the plurality of keys are moved to the stored positions.

16. The electronic device of claim 15, wherein the plurality of lifting members are adapted to move the plurality of keys away from the plurality of receiving cavities when the plurality of keys are moved to the extended positions.

17. The electronic device of claim 15, further comprising a plurality of blocking mechanisms defined in the plurality of receiving cavities, the plurality of blocking mechanisms are adapted to prevent the plurality of keys from being pressed down when the plurality of keys are retracted in the plurality of receiving cavities.

18. The electronic device of claim 17, wherein each of the plurality of blocking mechanism comprises two blocking plates, each of the plurality of receiving cavities defines two sidewalls, each of the two blocking plates being located on each of the two sidewalls.

19. The electronic device of claim 14, further comprising a light sensor disposed on the base member, the light sensor is adapted to generate the extending instruction when the light sensor detects an object in a predetermined distance.

20. The electronic device of claim 19, wherein the light sensor is adapted to generate the retracting instruction when the light sensor has not detected an object in the predetermined distance for a predetermined period of time.
